(19) United States
(12) Patent Application Publication
(10) Pub. No.: US 2019/0006016 A1
(43) Pub. Date: Jan. 3, 2019

(54) METHOD, SYSTEM, AND APPARATUS FOR DETECTING FAILURE OF PROGRAMMING OF A MEMORY DEVICE

(71) Applicant: INTEL CORPORATION, Santa Clara, CA (US)

(72) Inventors: Ali KHAKIFIROOZ, Los Altos, CA (US); Pranav KALAVADE, San Jose, CA (US); Shantanu R. RAJWADE, Santa Clara, CA (US); Aliasgar S. MADRASWALA, Folsom, CA (US); Uday CHANDRASEKHAR, Santa Clara, CA (US); Purval S. SULE, Folsom, CA (US); Sagar UPADHYAY, Folsom, CA (US)

(21) Appl. No.: 15/638,260

(22) Filed: Jun. 29, 2017

(51) Int. Cl. G11C 16/34; G11C 16/10; G11C 8/06; G11C 8/10; G06F 11/14

(52) U.S. Cl. CPC G11C 16/3454; G11C 16/10; G11C 16/3459; G11C 8/10; G06F 11/1402; G11C 8/06

(57) ABSTRACT

A programming of a memory device configurable to reach a plurality of voltage levels is initiated. For each voltage level to be reached, a checkpoint is set up within a sequence of program pulses applied for the programming of the memory device, to determine whether a plurality of memory cells of the memory device have reached the voltage level. The programming of the memory device is aborted, in response to determining at the checkpoint that the plurality of memory cells have not reached the voltage level.

### BACKGROUND

A solid state drive (SSD) is a data storage device that uses integrated circuit assemblies as memory to store data persistently. SSDs have no moving mechanical components and this distinguishes SSDs from traditional electromechanical magnetic disks, such as, hard disk drives (HDDs) or floppy disks, which contain spinning disks and movable read/write heads. Compared to electromechanical disks, SSDs are typically more resistant to physical shock, run silently, have lower access time, and less latency. Many types of SSDs use NAND-based flash memory which comprises an electronic (solid-state) non-volatile computer storage medium that can be electrically erased and reprogrammed.

NAND-based flash memory stores information (i.e., data) in individual memory cells. In single-level cell (SLC) NAND flash technology, each memory cell may exist in one of two voltage states, storing one bit of information per memory cell. A multi-level cell (MLC) is a memory cell capable of storing more than a single bit of information. For example, a MLC NAND flash memory that has four possible voltage states per memory cell may store two bits of information per memory cell, and MLC NAND flash memory that has eight possible voltage states per memory cell [typically referred to as Triple Level Cell (TLC NAND)], may store three bits of information per memory cell.

### BRIEF DESCRIPTION OF THE DRAWINGS

Referring now to the drawings in which like reference numbers represent corresponding parts throughout:

FIG. 1 illustrates a block diagram of a computing environment in which a host is coupled to a SSD comprised of MLC NAND memory, in accordance with certain embodiments;

FIG. 2 illustrates a block diagram that shows a sequence of program pulses of increasing magnitude being applied to a plurality of memory cells, followed by a series of verification operations for the plurality of memory cells, in accordance with certain embodiments;

FIG. 3 illustrates a block diagram that shows the progression of threshold distribution of memory cells during a series of programming operations, in accordance with certain embodiments;

FIG. 4 illustrates a block diagram that shows expected start and end program pulses, in accordance with certain embodiments;

FIG. 5 illustrates a block diagram that shows impact of a localized defect that affects the threshold distribution of memory cells from non-defective regions by exposing the memory cells from non-defective regions to excessive program disturbs, in accordance with certain embodiments;

FIG. 6 illustrates a block diagram that shows how PASS checkpoints are used to limit program disturbs, in accordance with certain embodiments;

FIG. 7 illustrates a block diagram that shows how FAIL checkpoints are used to limit program disturbs, in accordance with certain embodiments;

FIG. 8 illustrates the tiling of a die in which PASS and FAIL checkpoints are used, in accordance with certain embodiments;

FIG. 9 illustrates a flowchart for limiting program disturbs in a MLC NAND, in accordance with certain embodiments; and

FIG. 10 illustrates a block diagram of a system, in accordance with certain embodiments.

### DETAILED DESCRIPTION

In the following description, reference is made to the accompanying drawings which form a part hereof and which illustrate several embodiments. It is understood that other embodiments may be utilized and structural and operational changes may be made.

A MLC NAND device may be programmed by applying a series of program pulses with increasing magnitude of voltage, and verifying whether memory cells of the MLC NAND device reach threshold levels of voltages.

In certain situations, local defects may be present in a MLC NAND device that may cause a group of memory cells of the MLC NAND device to be slower to program than expected. Certain embodiments provide mechanisms to detect failure of programming of the MLC NAND device caused by the local defects, at lower levels of applied voltages, and prevent excessive program disturbs caused by excessive applied voltages on other memory cells that share the same local or global wordlines as the memory cells associated with the local defects. A program disturb occurs when one or more memory cells are programmed excessively.

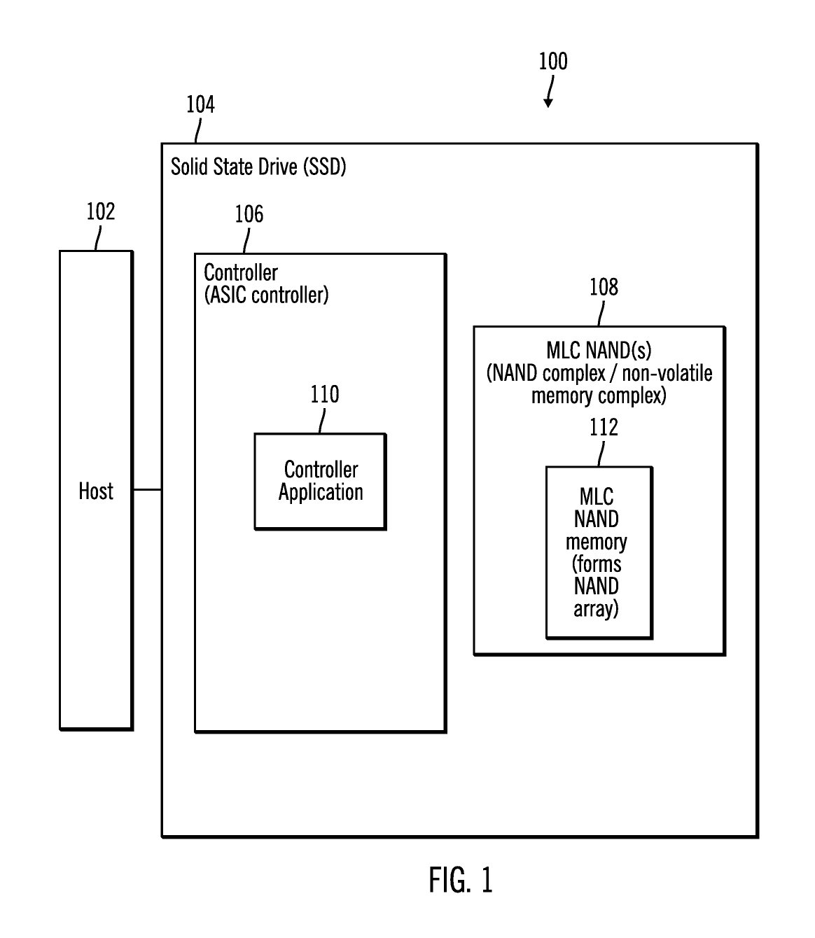

FIG. 1 illustrates a block diagram of a computing environment 100 in which a host 102 is coupled to a SSD 104, in accordance with certain embodiments. The SSD 104 may be comprised of a controller 106 and a NAND complex 108. The NAND complex 108 may also be referred to as a non-volatile memory complex that is comprised of a plurality of non-volatile memory modules that are directly or indirectly coupled, i.e., the non-volatile memory modules that are directly or indirectly coupled form a complex that is referred to as a non-volatile memory complex. In certain embodiments, the NAND complex 108 may be comprised of a plurality of NAND memory 112 that may form a NAND array. In certain embodiments the NAND complex 108 may be a MLC NAND, TLC NAND, Quad Level Cell (QLC) NAND or any other type of NAND or any other type of non-volatile memory complex, where each of the memory cells of the NAND complex 108 in the SSD 104 may store more than 1 bit of information. In other embodiments, the SSD 104 may be comprised of a controller 106 that controls certain other types of non-volatile memory, such as NOR memory or some other suitable non-volatile memory. Non-volatile memory is a storage medium that does not require power to maintain the state of data stored by the medium. Nonlimiting examples of nonvolatile memory may include any or a combination of: solid state memory [such as planar or three Dimensional (3D) NAND flash memory or NOR flash memory], 3D crosspoint memory, storage devices that use chalcogenide phase change material (e.g., chalcogenide glass), byte addressable nonvolatile memory devices, multi-threshold level NAND flash memory, ferroelectric memory, silicon-oxide-nitride-oxide-silicon (SONOS) memory, polymer memory (e.g., ferroelectric polymer memory), ferroelectric transistor random access memory (Fe-TRAM) ovonic memory, nanowire memory, electrically erasable programmable read-only memory (EEPROM), other various types of non-volatile random access memories (RAMs), magnetic storage memory, single or multi-level Phase Change Memory (PCM), a resistive memory, nanowire memory, anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device. In some embodiments, 3D crosspoint memory may comprise a transistor-less stackable cross point architecture in which memory cells sit at the intersection of words lines and bit lines and are individually addressable and in which bit storage is based on a change in bulk resistance. The memory device may refer to the die itself and/or to a packaged memory product. In certain embodiments, a memory module with non-volatile memory may comply with one or more standards promulgated by the Joint Electron Device Engineering Council (JEDEC), such as JESD218, JESD219, JESD220-1, JESD223B, JESD223-1, or other suitable standard (the JEDEC standards cited herein are available at www.jedec.org). In certain embodiments, the SSD 104 may be capable of storing several terabytes of data or more, and the NAND complex 108 may be comprised of a plurality of MLC NAND memory 112 that may form a NAND array.

In certain embodiments, the host 102 may be comprised of any suitable computational device, such as a personal computer, a mainframe, a telephony device, a smart phone, a storage controller, a blade computer, a processor with memory, etc. In certain embodiments, the host 102 may communicate with the SSD 104 over a bus (such as a Peripheral Component Interconnect (PCIe), Serial Advanced Technology Attachment (SATA), Serial Attached Small Computer System Interface (SAS)) or a network, such as the Internet, a storage area network (SAN), a local area network (LAN), Non-Volatile Memory Express (NVMe) a logical device interface (http://www.nvmexpress.org) for accessing non-volatile storage media attached via a PCIe bus, etc.

In certain embodiments, a controller application 110 (implemented in firmware, software, hardware or any combination thereof) that executes in the controller 106 of the SSD 104 programs the memory cells of the MLC NAND 108. The SSD 100 also receives commands from the host 102, and then the controller application 110 executes the read and/or write with respect to the NAND complex 108 by converting the read and/or write commands received from the host 102 into memory operations. The controller 106 and the controller application 110 may be implemented in Application Specific Integrated Circuit (ASIC) and/or firmware, software, or any combination thereof.

Therefore, FIG. 1 illustrates certain embodiments in which a controller application 110 programs the memory cells of the MLC NAND 108.

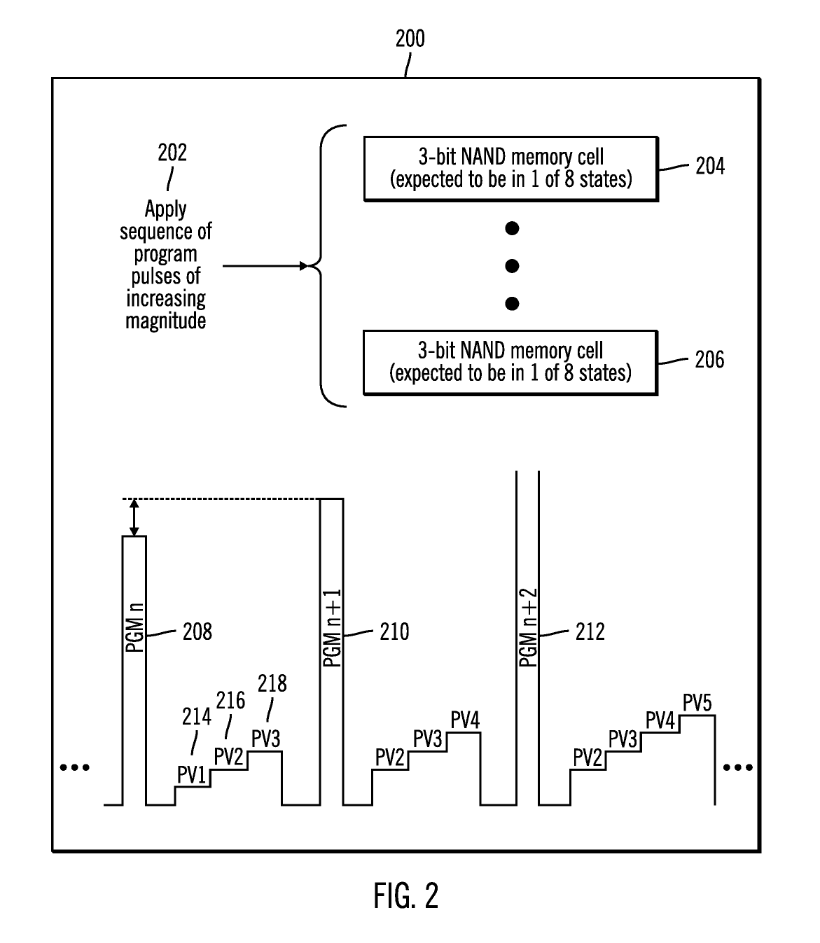

FIG. 2 illustrates a block diagram 200 that shows a sequence of program pulses 202 of increasing magnitudes of voltage being applied to a plurality of memory cells 204, 206 that may be included in the non-volatile memory complex 108 of the solid state drive 104. Following each program pulse, a series of verification operations are performed for the plurality of memory cells 204, 206, to determine how many of the memory cells reached a threshold voltage level corresponding to a voltage state. While FIG. 2 shows the memory cells to be TLC NAND memory cells with 8 voltage levels, the embodiments are applicable to other types of memory cells.

FIG. 2 also shows that programming a NAND device by applying a series of program pulses 208, 210, 212 with increasing magnitude of voltage to the control gate of the NAND cells 204, 206. Each programming pulse is followed by a series of verify steps 214, 216, 218 to compare the threshold voltage of the NAND cells against specified verify levels.

For example, in a TLC NAND device, each memory cell 204, 206 is programmed into one of 8 possible threshold voltage levels (L0, L1, . . . , L7) to represent 3 bits of data that is written to that memory cell. Each programming loop comprises applying a program pulse (denoted by PGM n 208, PGM n+1 210, PGM n+2 212) and a series of verify levels that may be referred to as PV1, PV2, PV3, PV4, PV5, PV6, PV7, where reference numerals 214, 216, 218 shows the verify levels applied after the program pulse PGM n 208. As the magnitude of the program pulse increases in each programming loop, the threshold voltage of the NAND memory cells that are being programmed increases. Once each memory cell's threshold voltage passes the corresponding verify level, the memory cell is inhibited in the remaining program loops by applying a higher voltage to the bitline of the memory cell.

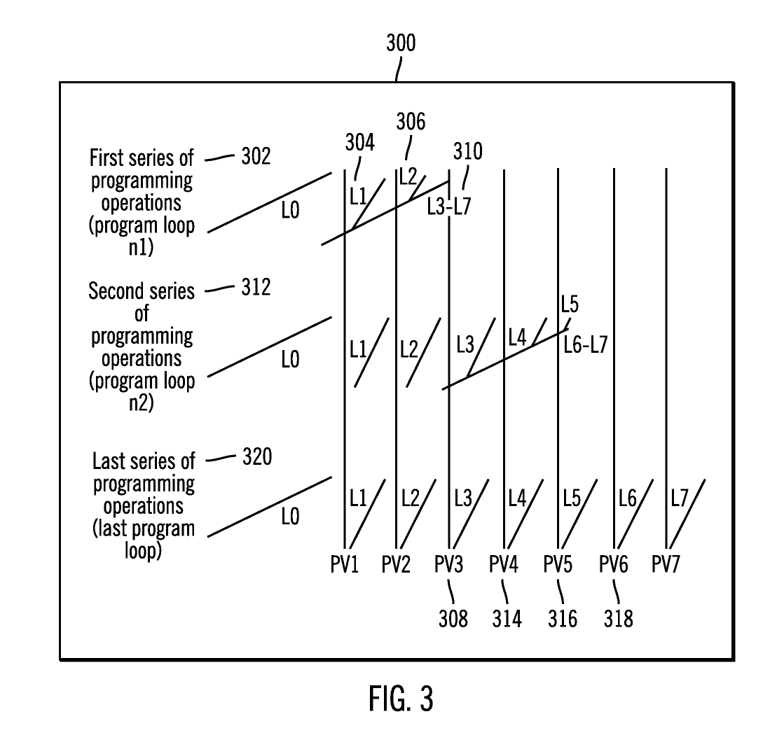

FIG. 3 illustrates a block diagram 300 that shows the progression of threshold distribution of memory cells during program loops in the exemplary MLC NAND 108, in accordance with certain embodiments.

As the magnitude of the program pulse is increased, the threshold (Vt) distribution of memory cells moves to a higher value based on the program slope of the memory cells. The Vt distribution is shown cumulatively. At a given program loop denoted by loop n1 302, the programmed Vt distribution has passed the verify levels for L1 and L2, but has not reached PV3 308 yet. The program operations verify the threshold voltage of cells that are targeted for L1 and L2 against PV1 and PV2, respectively and inhibit the bitlines that pass their corresponding verify levels. There is no need to verify cells that belong to L3-L7 310 yet. At a later program loop denoted by loop n2 312, all cells that belong to L1 and L2 have already passed their corresponding verify level and are inhibited for the rest of the program loops. There is no need to verify these cells any more. Program's Vt distribution has crossed PV3-PV5 308, 314, 316, but not PV6 318 as yet. As a result memory cells that belong to L3-L5 are being verified against their corresponding verify level. There is no need to verify cells that belong to L6 and L7. At a given program loop denoted by last program loop 320, all cells have passed their corresponding verify level and program operations complete successfully.

The expected loop number at which the program Vt distribution passes a given verify level (and as a result cells that belong to the corresponding level need to be verified) and expected loop number at which all cells that belong to a given level are expected to pass verify may be calculated based on the program slope of the memory cells, the gate step of increasing program pulses and spacing between the verify levels.

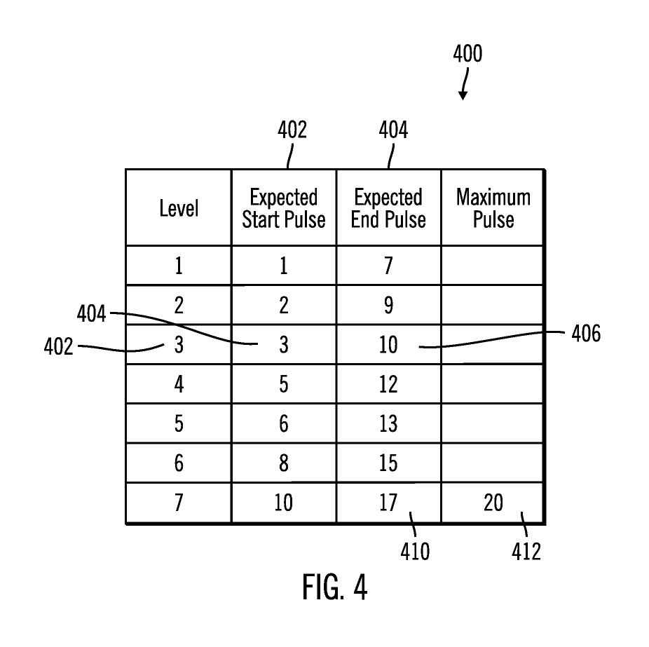

FIG. 4 illustrates a block diagram 400 that shows expected start 402 and end 404 program pulses. FIG. 4 shows expected loop numbers for an exemplary MLC NAND based device 104.

In this example shown in FIG. 4, it is expected that L3 402 starts verify at program loop 3 404 and finishes verifying all cells at program loop 10 406. All levels are expected to pass verify by program loop 17 410. Typically a maximum loop count is specified; if all cells are not verified by this maximum loop count, program is aborted with a fail status. In this example, the maximum loop count may be set to a number larger than 17; for example the maximum loop count may be set equal to 20 (reference numeral 412) to allow some margin for some variations in program slope, start voltage differences, etc.

In some embodiments, local defects may be present in a NAND device that may cause a group of cells to be slower to program than expected. One such localized defect may be electrical shorts between neighboring local wordlines that are created during fabrication process or during device operation as a result of high voltage stress applied to wordlines. This prevents the correct program or verify voltage to be applied to a group of cells and as a result they may not be programmed correctly or pass verify even if their threshold voltage is already above the corresponding PV level.

In certain embodiments, the programming operations do not have the information that these memory cells are localized to a specific region of the NAND die or does not use this information even if the information is available. As a result the programming operations may treat such localized defects merely as if some of the cells are still not passing verify and may continue to increase the magnitude of voltage of the program pulse until the maximum loop count is reached (e.g., loop count of 20 as shown via reference numeral 412). As a consequence, other memory cells that share the same local or global word line are exposed to excessive program voltage and as a result program disturb. Program disturb may cause an increase to the threshold voltage of inhibited cells and in particular threshold voltage of cells that belong to L0. This may cause a read error for cells that share the same local or global wordline even if the defective location is excluded during read operations.

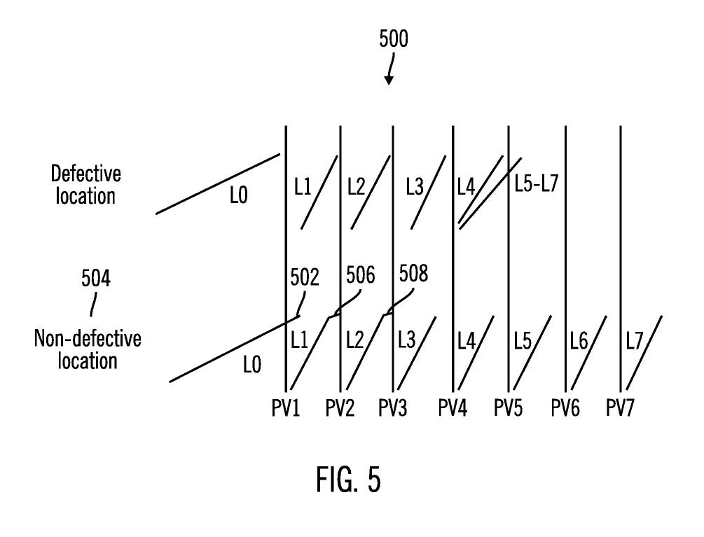

FIG. 5 illustrates a block diagram 500 that shows impact of a localized defect that affects the threshold distribution of memory cells from non-defective regions by exposing them to excessive program disturbs. It may be seen from reference numeral 502 that program disturb has caused an increase to the threshold voltage of inhibited memory cells that belong to L0 that are in non-defective location 504. Memory cells that belong to L1 and L2 are also affected as shown via reference numerals 506, 508.

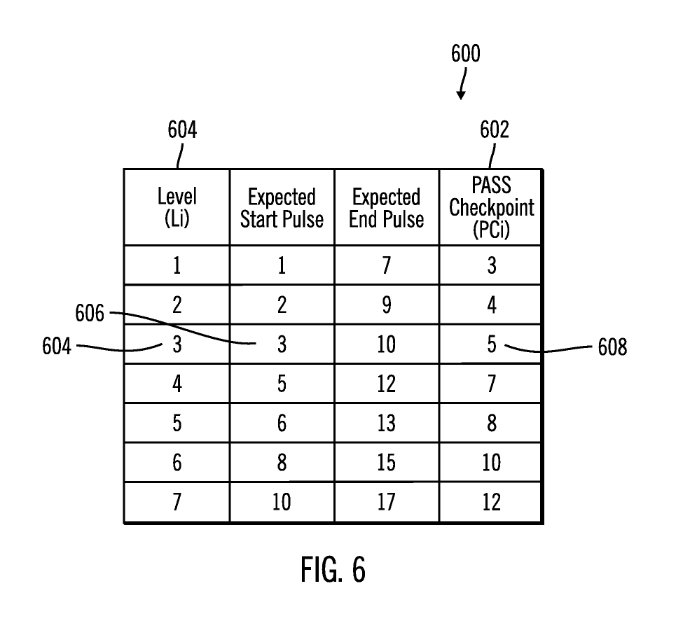

FIG. 6 illustrates a block diagram 600 that shows how PASS checkpoints are used to limit program disturbs, in accordance with certain embodiments. FIG. 6 shows how to identify slow to program memory cells earlier than the maximum loop count 412 shown in FIG. 3, by adding specific checkpoints at certain loop numbers.

In one embodiment, a set of PASS checkpoints (PCi) 602 are specified for each level, Li, 604. If at loop=PCi, the number of cells that belong to Li and that are passing PVi is less than a pre-specified threshold number, the programming is aborted and status fail is reported. The PASS checkpoints PCi are specified based on the expected loop number where some cells for a given level Li are expected to pass PVi. For example, from FIG. 5 for level 3 (reference numeral 604) it is expected that some memory cells pass verify at loop 3 (reference numeral 606). One plausible choice for PC₃ may be a number greater than 3, for example 5 (reference numeral 608). If by loop=5 the number of cells from L3 that pass PV3 is less than a given threshold, program operations abort and a failure status is reported. Since programming was aborted at loop=5 as opposed to waiting for the maximum loop (20 in the example shown via reference numeral 412 in FIG. 4), other cells that share the same local or global wordline are not exposed to excessive program disturb.

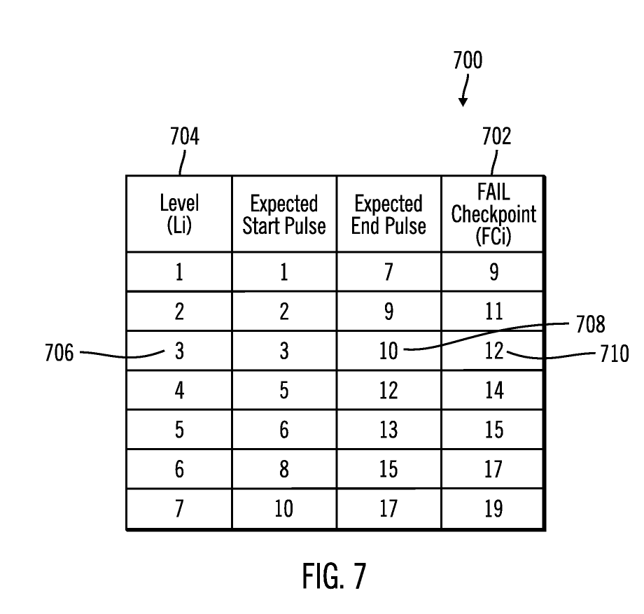

FIG. 7 illustrates a block diagram 700 that shows how fail checkpoints are used to limit program disturbs, in accordance with certain embodiments.

A set of FAIL checkpoints (FCi) 702 are specified for each level Li 704. If at loop=FCi the number of cells that belong to Li and fail PVi is greater than a pre-specified threshold number, the programming is aborted and a failure status is reported.

The FAIL checkpoints (FCi) 702 may be specified from the loop number at which all cells from a given level Li 704 are expected to pass verify. In the example shown in FIG. 7, cells from L3 706 are expected to pass by loop=10 (reference numeral 708). A plausible option for FC₃ is any number greater than 10, for example 12 (reference numeral 710). If by loop 12 (reference numeral 710) the number of failing cells from L3 706 is greater than a threshold, programming is aborted and status failure is reported.

In this example shown in FIG. 7, the program is aborted at pulse 12 (reference numeral 710) as opposed to waiting for maximum loop of 20 as shown via reference numeral 412 of FIG. 4. As a result other cells that share the same local or global word line are not exposed to excessive program disturb.

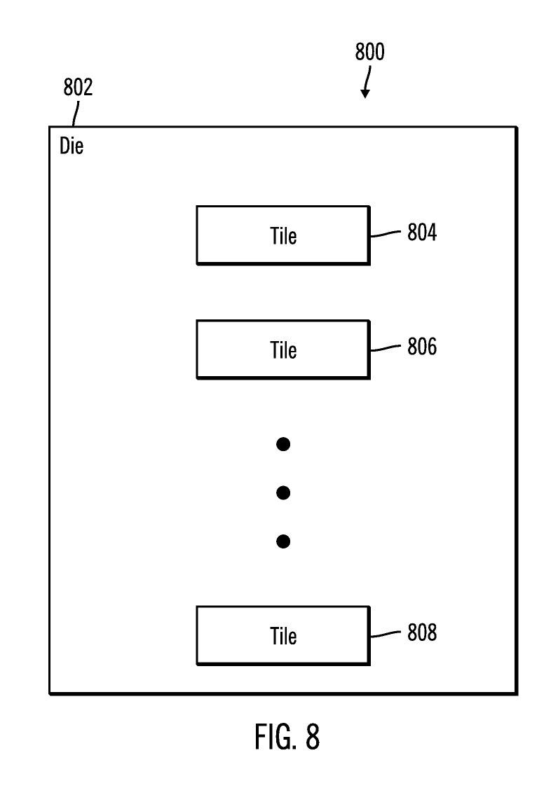

FIG. 8 is a block diagram 800 that illustrates the tiling of a die 802 in which PASS and FAIL checkpoints are used, in accordance with certain embodiments. The die 602 may be included in the MLC NANDs 108 of the memory device 104.

In one embodiment the die 802 is divided into portions or regions referred to as tiles 804, 806, 808. Each tile is comprised of cells that share the same local wordline. A set of PASS checkpoints (PCi) 602 are specified for each level Li. If at loop PCi 602 the number of cells that belong to Li 604 and passing PVi is less than a pre-specified threshold for a given tile, that tile is excluded from programming in the rest of programming loops and program operations continue.

In an alternative embodiment, the die 802 is divided into portions or regions referred to as tiles 804, 806, 808. A set of FAIL checkpoints (FCi) 702 are specified for levels Li 704. If at loop FCi the number of cells that belong to Li and fail PVi is greater than a pre-specified threshold for a given tile, the tile is excluded from programming in the rest of programming loops and program operations continue.

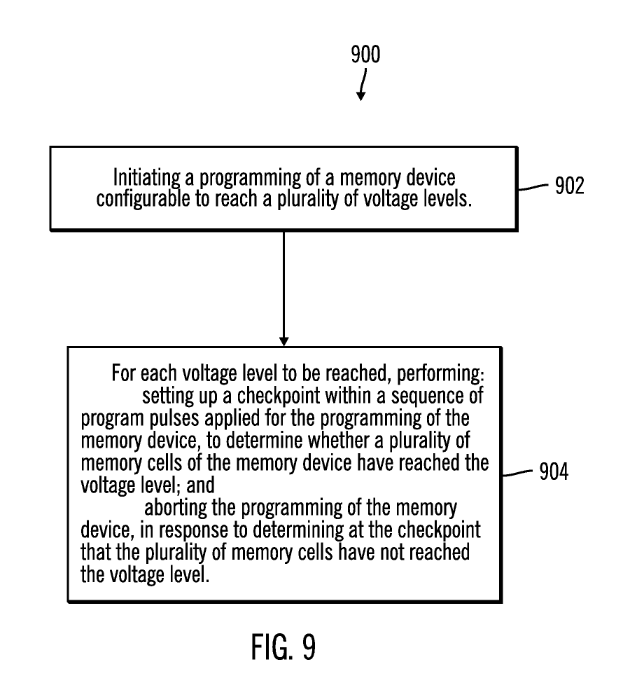

FIG. 9 illustrates a flowchart 900 for limiting program disturbs in a MLC NAND device 104, in accordance with certain embodiments. The operations shown in FIG. 9 may be performed by the controller 106 in association with the MLC NAND 108 of the MLC NAND device.

Control starts at block 902 in which a programming of a memory device configurable to reach a plurality of voltage levels is initiated. In certain embodiments, the sequence of program pulses are applied in an increasing order of magnitude, wherein application of each program pulse is followed by one or more verification operations to determine whether voltage levels have been reached in the plurality of memory cells of the memory device.

From block 902 control proceeds to block 904. For each voltage level to be reached, a checkpoint is set up (at block 904) within a sequence of program pulses applied for the programming of the memory device, to determine whether a plurality of memory cells of the memory device have reached the voltage level. The programming of the memory device is aborted (also at block 904), in response to determining at the checkpoint that the plurality of memory cells have not reached the voltage level.

Therefore FIGS. 1-9 illustrate certain embodiments in which in a multi-level per cell programming mechanism, certain embodiments add additional checkpoints in the programming loop. If at a specified checkpoint a certain level is not passing verify, the program aborts. This prevents excessive program voltages from being applied to other cells that share the same local or global wordline as a localized defect, and program disturbs are reduced.

The described operations may be implemented as a method, apparatus or computer program product using standard programming and/or engineering techniques to produce software, firmware, hardware, or any combination thereof. The described operations may be implemented as code maintained in a “computer readable storage medium”, where a processor may read and execute the code from the computer storage readable medium. The computer readable storage medium includes at least one of electronic circuitry, storage materials, inorganic materials, organic materials, biological materials, a casing, a housing, a coating, and hardware. A computer readable storage medium may comprise, but is not limited to, a magnetic storage medium (e.g., hard disk drives, floppy disks, tape, etc.), optical storage (CD-ROMs, DVDs, optical disks, etc.), volatile and non-volatile memory devices (e.g., EEPROMs, ROMs, PROMs, RAMs, DRAMs, SRAMs, Flash Memory, firmware, programmable logic, etc.), Solid State Devices (SSD), etc. The code implementing the described operations may further be implemented in hardware logic implemented in a hardware device (e.g., an integrated circuit chip, Programmable Gate Array (PGA), Application Specific Integrated Circuit (ASIC), etc.). Still further, the code implementing the described operations may be implemented in “transmission signals”, where transmission signals may propagate through space or through a transmission media, such as an optical fiber, copper wire, etc. The transmission signals in which the code or logic is encoded may further comprise a wireless signal, satellite transmission, radio waves, infrared signals, Bluetooth, etc. The program code embedded on a computer readable storage medium may be transmitted as transmission signals from a transmitting station or computer to a receiving station or computer. A computer readable storage medium is not comprised solely of transmission signals. Those skilled in the art will recognize that many modifications may be made to this configuration, and that the article of manufacture may comprise suitable information bearing medium known in the art.

Computer program code for carrying out operations for aspects of the certain embodiments may be written in any combination of one or more programming languages. Blocks of the flowchart and block diagrams may be implemented by computer program instructions.

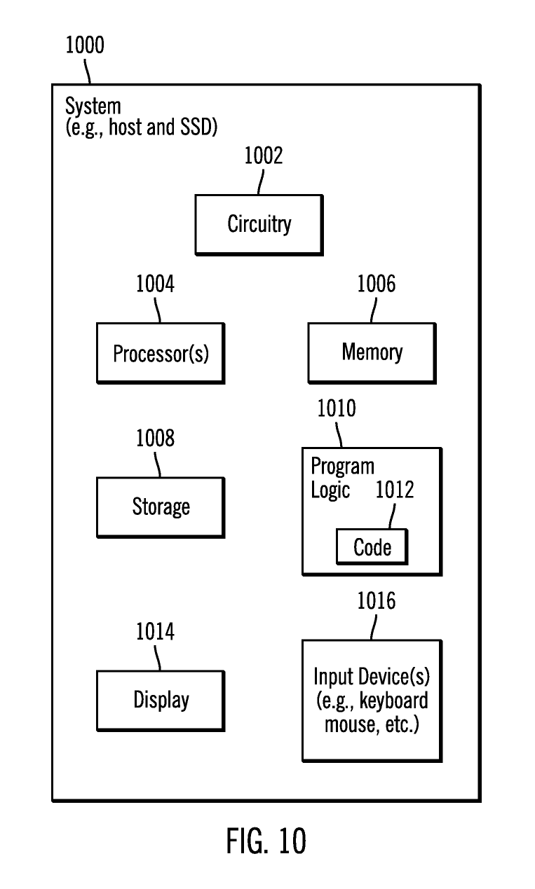

FIG. 10 illustrates a block diagram of a system 1000 that includes both the host 102 (the host 102 comprises at least a processor) and the solid state drive 104, in accordance with certain embodiments. For example, in certain embodiments the system 1000 may be a computer (e.g., a laptop computer, a desktop computer, a tablet, a cell phone or any other suitable computational device) that has the host 102 and the solid state drive 104 both included in the system 1000. For example, in certain embodiments the system 1000 may be a laptop computer that includes the solid state drive 102. The system 1000 may include a circuitry 1002 that may in certain embodiments include at least a processor 1004. The system 1000 may also include a memory 1006 (e.g., a volatile memory device), and storage 1008. The storage 1008 may include the solid state drive 104 or other drives or devices including a non-volatile memory device (e.g., EEPROM, ROM, PROM, flash, firmware, programmable logic, etc.). The storage 1008 may also include a magnetic disk drive, an optical disk drive, a tape drive, etc. The storage 1008 may comprise an internal storage device, an attached storage device and/or a network accessible storage device. The system 1000 may include a program logic 1010 including code 1012 that may be loaded into the memory 1006 and executed by the processor 1004 or circuitry 1002. In certain embodiments, the program logic 1010 including code 1012 may be stored in the storage 1008. In certain other embodiments, the program logic 1010 may be implemented in the circuitry 1002. Therefore, while FIG. 10 shows the program logic 1010 separately from the other elements, the program logic 1010 may be implemented in the memory 1006 and/or the circuitry 1002. The system 1000 may also include a display 1014 (e.g., an liquid crystal display (LCD), a light emitting diode (LED) display, a cathode ray tube (CRT) display, a touchscreen display, or any other suitable display). The system 1000 may also include one or more input devices 1016, such as, a keyboard, a mouse, a joystick, a trackpad, or any other suitable input devices). Other components or devices beyond those shown in FIG. 10 may also be found in the system 1000.

Certain embodiments may be directed to a method for deploying computing instruction by a person or automated processing integrating computer-readable code into a computing system, wherein the code in combination with the computing system is enabled to perform the operations of the described embodiments.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments.

Further, although process steps, method steps, algorithms or the like may be described in a sequential order, such processes, methods and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified or removed. Moreover, steps may be added to the above described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

### EXAMPLES

The following examples pertain to further embodiments.

Examiner 1 is a method for detecting programming failure in which a programming of a memory device configurable to reach a plurality of voltage levels is initiated. For each voltage level to be reached, a checkpoint is set up within a sequence of program pulses applied for the programming of the memory device, to determine whether a plurality of memory cells of the memory device have reached the voltage level. The programming of the memory device is aborted, in response to determining at the checkpoint that the plurality of memory cells have not reached the voltage level.

In example 2, the subject matter of example 1 may include that programming the memory device comprises applying the sequence of program pulses in an increasing order of magnitude, wherein application of each program pulse is followed by one or more verification operations to determine whether voltage levels have been reached in the plurality of memory cells of the memory device.

In example 3, the subject matter of example 1 may include that the memory device is a multi-level cell (MLC) memory device, and wherein one checkpoint is set for each voltage level of the plurality of voltage levels.

In example 4, the subject matter of example 1 may include that one checkpoint is set for each voltage level of the plurality of voltage levels, wherein for each checkpoint for a voltage level if a number of memory cells that reach the voltage level is less than a predetermined threshold number, then programming of the memory device is aborted and a status failure is reported.

In example 5, the subject matter of example 1 may include that a checkpoint for a voltage level is after an expected start pulse and prior to an expected end pulse for the voltage level.

In example 6, the subject matter of example 1 may include that a checkpoint is set for each voltage level of the plurality of voltage levels. A die of the memory device is segmented into a plurality of regions, wherein each region comprises memory cells that share a same local wordline. For each checkpoint for a voltage level, if a number of memory cells that reach the voltage level in a region is less than a predetermined threshold number, then excluding the region from being programmed while continuing programming of other regions of the memory device.

In example 7, the subject matter of example 1 may include that one checkpoint is set for each voltage level of the plurality of voltage levels, wherein for each checkpoint for a voltage level if a number of memory cells that fail to reach the voltage level is more than a predetermined threshold number, then programming of the memory device is aborted and a status failure is reported.

In example 8, the subject matter of example 1 may include that a checkpoint for a voltage level is after an expected end pulse for the voltage level.

In example 9, the subject matter of example 1 may include that a checkpoint is set for each voltage level of the plurality of voltage levels. A die of the memory device is segmented into a plurality of regions, wherein each region comprises memory cells that share a same local wordline. For each checkpoint for a voltage level, if a number of memory cells that fail to reach the voltage level in a region is more than a predetermined threshold number, then excluding the region from being programmed while continuing programming of other regions of the memory device.

Example 10 is a non-volatile memory device for detecting programming failure, the non-volatile memory device comprising: a non-volatile memory; and a controller coupled to the non-volatile memory, wherein the controller is operable to: initiate a programming of the non-volatile memory, wherein the non-volatile memory is configurable to reach a plurality of voltage levels; and for each voltage level to be reached, perform: set up a checkpoint within a sequence of program pulses applied for the programming of the non-volatile memory, to determine whether a plurality of memory cells of the non-volatile memory have reached the voltage level; and abort the programming of the non-volatile memory, in response to determining at the checkpoint that the plurality of memory cells have not reached the voltage level.

In example 11, the subject matter of example 10 may include that programming the non-volatile memory comprises applying the sequence of program pulses in an increasing order of magnitude, wherein application of each program pulse is followed by one or more verification operations to determine whether voltage levels have been reached in the plurality of memory cells of the non-volatile memory.

In example 12, the subject matter of example 10 may include that the non-volatile memory device is a multi-level cell (MLC) memory device, and wherein one checkpoint is set for each voltage level of the plurality of voltage levels.

In example 13, the subject matter of example 10 may include that one checkpoint is set for each voltage level of the plurality of voltage levels, and wherein for each checkpoint for a voltage level if a number of memory cells that reach the voltage level is less than a predetermined threshold number, then programming of the non-volatile memory is aborted and a status failure is reported.

In example 14, the subject matter of example 10 may include that a checkpoint for a voltage level is after an expected start pulse and prior to an expected end pulse for the voltage level.

In example 15, the subject matter of example 10 may include that a checkpoint is set for each voltage level of the plurality of voltage levels, wherein the controller is further operable to: segment a die of the non-volatile memory device into a plurality of regions, wherein each region comprises memory cells that share a same local wordline; and for each checkpoint for a voltage level, if a number of memory cells that reach the voltage level in a region is less than a predetermined threshold number, then exclude the region from being programmed while continuing programming of other regions of the non-volatile memory.

In example 16, the subject matter of example 10 may include that one checkpoint is set for each voltage level of the plurality of voltage levels, and wherein for each checkpoint for a voltage level if a number of memory cells that fail to reach the voltage level is more than a predetermined threshold number, then programming of the non-volatile memory is aborted and a status failure is reported.

In example 17, the subject matter of example 10 may include that a checkpoint for a voltage level is after an expected end pulse for the voltage level.

In example 18, the subject matter of example 10 may include that a checkpoint is set for each voltage level of the plurality of voltage levels, wherein the controller is further operable to: segment a die of the non-volatile memory device into a plurality of regions, wherein each region comprises memory cells that share a same local wordline; and for each checkpoint for a voltage level, if a number of memory cells that fail to reach the voltage level in a region is more than a predetermined threshold number, then exclude the region from being programmed while continuing programming of other regions of the non-volatile memory.

Example 19 is a system detecting programming failure, the system comprising: a display; a non-volatile memory device comprising a non-volatile memory; and a controller coupled to the non-volatile memory, wherein the controller is operable to: initiate a programming of the non-volatile memory, wherein the non-volatile memory is configurable to reach a plurality of voltage levels; and for each voltage level to be reached, perform: set up a checkpoint within a sequence of program pulses applied for the programming of the non-volatile memory, to determine whether a plurality of memory cells of the non-volatile memory have reached the voltage level; and abort the programming of the non-volatile memory, in response to determining at the checkpoint that the plurality of memory cells have not reached the voltage level.

In example 20, the subject matter of example 19 may include that programming the non-volatile memory comprises: applying the sequence of program pulses in an increasing order of magnitude, wherein application of each program pulse is followed by one or more verification operations to determine whether voltage levels have been reached in the plurality of memory cells of the non-volatile memory.

In example 21, the subject matter of example 19 may include that the non-volatile memory device is a multi-level cell (MLC) memory device, and wherein one checkpoint is set for each voltage level of the plurality of voltage levels.

In example 22, the subject matter of example 19 may include that one checkpoint is set for each voltage level of the plurality of voltage levels, and wherein for each checkpoint for a voltage level if a number of memory cells that reach the voltage level is less than a predetermined threshold number, then programming of the non-volatile memory is aborted and a status failure is reported.

In example 23, the subject matter of example 19 may include that a checkpoint for a voltage level is after an expected start pulse and prior to an expected end pulse for the voltage level.

In example 24, the subject matter of example 19 may include that a checkpoint is set for each voltage level of the plurality of voltage levels, wherein the controller is further operable to: segment a die of the non-volatile memory device into a plurality of regions, wherein each region comprises memory cells that share a same local wordline; and for each checkpoint for a voltage level, if a number of memory cells that reach the voltage level in a region is less than a predetermined threshold number, then exclude the region from being programmed while continuing programming of other regions of the non-volatile memory.

In example 25, the subject matter of example 19 may include that one checkpoint is set for each voltage level of the plurality of voltage levels, and wherein for each checkpoint for a voltage level if a number of memory cells that fail to reach the voltage level is more than a predetermined threshold number, then programming of the non-volatile memory is aborted and a status failure is reported.

Example 26 is a system detecting programming failure, the system comprising: means for initiating a programming of a memory device configurable to reach a plurality of voltage levels; and means for performing for each voltage level to be reached comprising: means for setting up a checkpoint within a sequence of program pulses applied for the programming of the memory device, to determine whether a plurality of memory cells of the memory device have reached the voltage level; and means for aborting the programming of the memory device, in response to determining at the checkpoint that the plurality of memory cells have not reached the voltage level.

All optional features of any of the systems and/or apparatus described above may also be implemented with respect to the method or process described above, and specifics in the examples may be used anywhere in one or more embodiments. Additionally, all optional features of the method or process described above may also be implemented with respect to any of the system and/or apparatus described above, and specifics in the examples may be used anywhere in one or more embodiments.

1. A method, comprising:
aborting a programming of a memory device, in response to:
determining at a first checkpoint that a first plurality of memory cells of the memory device have not reached a first voltage level, wherein the first checkpoint is after a start pulse and prior to an end pulse for the first voltage level; and
determining at a second checkpoint that a second plurality of memory cells of the memory device have not reached a second voltage level, wherein the second checkpoint is after a start pulse and prior to an end pulse for the second voltage level.

2. The method of claim 1, wherein the start pulse and the end pulse for the first voltage level and the start pulse and the end pulse of the second voltage level are included in a sequence of program pulses, and wherein the programming the memory device comprises:
applying the sequence of program pulses in an increasing order of magnitude, wherein application of each program pulse is followed by one or more verification operations to determine whether voltage levels have been reached in the first and the second plurality of memory cells of the memory device.

3. The method of claim 1, wherein the memory device is a multi-level cell (MLC) memory device, and wherein one checkpoint is set for each voltage level of a plurality of voltage levels.

4. (canceled)

5. (canceled)

6. The method of claim 1, wherein a checkpoint is set for each voltage level of a plurality of voltage levels, the method further comprising:
segmenting a die of the memory device into a plurality of regions, wherein each region comprises memory cells that share a same local wordline; and
for the first checkpoint, if a number of memory cells that reach the first voltage level in a region is less than a predetermined threshold number, then excluding the region from being programmed while continuing programming of other regions of the memory device.

7-9. (canceled)

10. A non-volatile memory device, comprising:
a non-volatile memory; and
a controller coupled to the non-volatile memory, wherein the controller is configured to abort a programming of the non-volatile memory, in response to:
a determination at a first checkpoint that a first plurality of memory cells of the non-volatile memory have not reached a first voltage level, wherein the first checkpoint is after a start pulse and prior to an end pulse for the first voltage level; and
a determination at a second checkpoint that a second plurality of memory cells of the non-volatile memory have not reached a second voltage level, wherein the second checkpoint is after a start pulse and prior to an end pulse for the second voltage level.

11. The non-volatile memory device of claim 10, wherein the start pulse and the end pulse for the first voltage level and the start pulse and the end pulse of the second voltage level are included in a sequence of program pulses, and wherein the programming the non-volatile memory comprises:
applying the sequence of program pulses in an increasing order of magnitude, wherein application of each program pulse is followed by one or more verification operations to determine whether voltage levels have been reached in the first and the second plurality of memory cells of the non-volatile memory.

12. The non-volatile memory device of claim 10, wherein the non-volatile memory device is a multi-level cell (MLC) memory device, and wherein one checkpoint is set for each voltage level of a plurality of voltage levels.

13-14. (canceled)

15. The non-volatile memory device of claim 10, wherein a checkpoint is set for each voltage level of a plurality of voltage levels, wherein the controller is further configured to:
segment a die of the non-volatile memory device into a plurality of regions, wherein each region comprises memory cells that share a same local wordline; and
for the first checkpoint, if a number of memory cells that reach the first voltage level in a region is less than a predetermined threshold number, then excluding the region from being programmed while continuing programming of other regions of the non-volatile memory.

16-18. (canceled)

19. A system, comprising:
a display;
a non-volatile memory device comprising a non-volatile memory; and
a controller coupled to the non-volatile memory, wherein the controller is configured to abort a programming of the non-volatile memory, in response to:
a determination at a first checkpoint that a first plurality of memory cells of the non-volatile memory have not reached a first voltage level, wherein the first checkpoint is after a start pulse and prior to an end pulse for the first voltage level; and
a determination at a second checkpoint that a second plurality of memory cells of the non-volatile memory have not reached a second voltage level, wherein the second checkpoint is after a start pulse and prior to an end pulse for the second voltage level.

20. The system of claim 19, wherein the start pulse and the end pulse for the first voltage level and the start pulse and the end pulse of the second voltage level are included in a sequence of program pulses, and wherein the programming the non-volatile memory comprises:
applying the sequence of program pulses in an increasing order of magnitude, wherein application of each program pulse is followed by one or more verification operations to determine whether voltage levels have been reached in the first and the second plurality of memory cells of the non-volatile memory.

21. The non-volatile memory device of claim 19, wherein the non-volatile memory device is a multi-level cell (MLC) memory device, and wherein one checkpoint is set for each voltage level of a plurality of voltage levels.

22-23. (canceled)

24. The system of claim 19, wherein a checkpoint is set for each voltage level of a plurality of voltage levels, wherein the controller is further configured to:
segment a die of the non-volatile memory device into a plurality of regions, wherein each region comprises memory cells that share a same local wordline; and
for the first checkpoint, if a number of memory cells that reach the first voltage level in a region is less than a predetermined threshold number, then excluding the region from being programmed while continuing programming of other regions of the non-volatile memory.

25. (canceled)

26. The method of claim 1, wherein the first checkpoint and the second checkpoint correspond to a numerical indicator corresponding to a programming loop for the programming of the memory device.

27. The method of claim 1, the method further comprising:
aborting the programming of the memory device, in response to:
determining at a third checkpoint that a third plurality of memory cells of the memory device have failed to reach a third voltage level, wherein the third checkpoint is after an end pulse for the third voltage level.

28. The method of claim 27, wherein the programming of the memory device is also aborted in response to:
determining at a fourth checkpoint that a fourth plurality of memory cells of the memory device have failed to reach a fourth voltage level, wherein the fourth checkpoint is after an end pulse for the fourth voltage level.

29. The non-volatile memory device of claim 10, wherein the first checkpoint and the second checkpoint correspond to a numerical indicator corresponding to a programming loop for the programming of the non-volatile memory.

30. The non-volatile memory device of claim 10, wherein the controller is further configured to abort the programming of the non-volatile memory, in response to:
a determination at a third checkpoint that a third plurality of memory cells of the non-volatile memory have failed to reach a third voltage level, wherein the third checkpoint is after an end pulse for the third voltage level.

31. The non-volatile memory device of claim 30, wherein the programming of the non-volatile memory is also aborted in response to:
a determination at a fourth checkpoint that a fourth plurality of memory cells of the non-volatile memory have failed to reach a fourth voltage level, wherein the fourth checkpoint is after an end pulse for the fourth voltage level.

32. The system of claim 19, wherein the first checkpoint and the second checkpoint correspond to a numerical indicator corresponding to a programming loop for the programming of the non-volatile memory.

33. The system of claim 19, wherein the controller is further configured to abort the programming of the non-volatile memory, in response to:
a determination at a third checkpoint that a third plurality of memory cells of the non-volatile memory have failed to reach a third voltage level, wherein the third checkpoint is after an end pulse for the third voltage level.

34. The system of claim 33, wherein the programming of the non-volatile memory is also aborted in response to:
a determination at a fourth checkpoint that a fourth plurality of memory cells of the non-volatile memory have failed to reach a fourth voltage level, wherein the fourth checkpoint is after an end pulse for the fourth voltage level.
